(19) United States
(12) Patent Application Publication
(10) Pub. No.: US 2026/0149423 A1
(43) Pub. Date: May 28, 2026

(54) FLIPPED VOLTAGE FOLLOWER INCLUDING BIAS VOLTAGE CONTROL CIRCUIT FOR HEADROOM COMPENSATION

(71) Applicant: QUALCOMM Incorporated, San Diego, CA (US)

(72) Inventors: Andrew WEIL, San Diego, CA (US); Jaswinder SINGH, San Diego, CA (US); Parisa MAHMOUDIDARYAN, San Diego, CA (US)

(21) Appl. No.: 18/962,986

(22) Filed: Nov. 27, 2024

(51) Int. Cl. H03F 3/45

(52) U.S. Cl. CPC H03F 3/45475; H03F 2200/129

(57) ABSTRACT

An apparatus, including: a flipped voltage follower (FVF) including a first p-channel field effect transistor (PFET), a second PFET, and a first current source coupled in series between an upper voltage rail and a lower voltage rail; and a bias voltage control circuit coupled to a node between the second PFET and the first current source.

### FIELD

This disclosure relates generally to load driver amplifiers, and in particular, to a flipped voltage follower including a bias voltage control circuit for headroom compensation.

### BACKGROUND

A driver amplifier may be configured to amplify an input signal to generate an output signal with significant power or current to drive a load. Such driver amplifier may include a set of field effect transistors (FETs) coupled in series with a current source between an upper voltage rail and a lower voltage rail. In certain situations, a supply voltage at the upper voltage rail drops or is too low for any number of reasons (e.g., process corner, temperature, load on the upper voltage rail, etc.). In such situations, the FETs and the current source may collapse (e.g., failed to operate as intended) due to headroom issue as a result of the low supply voltage at the upper voltage rail.

### SUMMARY

The following presents a simplified summary of one or more implementations in order to provide a basic understanding of such implementations. This summary is not an extensive overview of all contemplated implementations, and is intended to neither identify key or critical elements of all implementations nor delineate the scope of any or all implementations. Its sole purpose is to present some concepts of one or more implementations in a simplified form as a prelude to the more detailed description that is presented later.

An aspect of the disclosure relates to an apparatus. The apparatus includes a flipped voltage follower (FVF) including a first p-channel field effect transistor (PFET), a second PFET, and a first current source coupled in series between an upper voltage rail and a lower voltage rail; and a bias voltage control circuit coupled to a node between the second PFET and the first current source.

Another aspect of the disclosure relates to an apparatus. The apparatus includes a flipped voltage follower (FVF) including a first current source, a first n-channel field effect transistor (NFET), and a second NFET coupled in series between an upper voltage rail and a lower voltage rail; and a bias voltage control circuit coupled to a node between the first current source and the first NFET.

Another aspect of the disclosure relates to a method of driving a load. The method includes providing an input signal to a gate of a first field effect transistor (FET) coupled between a current source and a second FET of a flipped voltage follower (FVF); generating an output signal for driving the load based on the input signal at an output of the FVF, wherein the output is coupled to a source of the first FET and a drain of the second FET; and controlling a voltage difference between a gate of the second FET and a node between the first FET and the current source.

To the accomplishment of the foregoing and related ends, the one or more implementations include the features hereinafter fully described and particularly pointed out in the claims. The following description and the annexed drawings set forth in detail certain illustrative aspects of the one or more implementations. These aspects are indicative, however, of but a few of the various ways in which the principles of various implementations may be employed and the description implementations are intended to include all such aspects and their equivalents.

### BRIEF DESCRIPTION OF THE DRAWINGS

FIG. 1 illustrates a block diagram of an example load (e.g., memory) driving circuit in accordance with an aspect of the disclosure.

FIG. 2 illustrates a block diagram of another example load (e.g., memory) driving circuit in accordance with another aspect of the disclosure.

FIG. 3 illustrates a schematic diagram of an example PFET-based source follower (SF) in accordance with another aspect of the disclosure.

FIG. 4 illustrates a schematic diagram of an example NFET-based source follower (SF) in accordance with another aspect of the disclosure.

FIG. 5 illustrates a schematic diagram of an example PFET-based flipped voltage follower (FVF) in accordance with another aspect of the disclosure.

FIG. 6 illustrates a schematic diagram of an example load driver amplifier in accordance with another aspect of the disclosure.

FIG. 7 illustrates a schematic diagram of another example load driver amplifier in accordance with another aspect of the disclosure.

FIG. 8 illustrates a schematic diagram of an example load driver amplifier including a PFET-based flipped voltage follower (FVF) and a bias voltage control circuit in accordance with another aspect of the disclosure.

FIG. 9 illustrates a schematic diagram of another example load driver amplifier including a PFET-based flipped voltage follower (FVF) and a bias voltage control circuit in accordance with another aspect of the disclosure.

FIG. 10 illustrates a schematic diagram of another example load driver amplifier including a PFET-based flipped voltage follower (FVF) and a PFET-based bias voltage control circuit in accordance with another aspect of the disclosure.

FIG. 11 illustrates a schematic diagram of an example load driver amplifier including an NFET-based flipped voltage follower (FVF) and a bias voltage control circuit in accordance with another aspect of the disclosure.

FIG. 12 illustrates a schematic diagram of another example load driver amplifier including an NFET-based flipped voltage follower (FVF) and a bias voltage control circuit in accordance with another aspect of the disclosure.

FIG. 13 illustrates a schematic diagram of another example load driver amplifier including an NFET-based flipped voltage follower (FVF) and an NFET-based bias voltage control circuit in accordance with another aspect of the disclosure.

FIG. 14 illustrates a flow diagram of an example method of driving a load in accordance with another aspect of the disclosure.

### DETAILED DESCRIPTION

The detailed description set forth below, in connection with the appended drawings, is intended as a description of various configurations and is not intended to represent the only configurations in which the concepts described herein may be practiced. The detailed description includes specific details for the purpose of providing a thorough understanding of the various concepts. However, it will be apparent to those skilled in the art that these concepts may be practiced without these specific details. In some instances, well-known structures and components are shown in block diagram form in order to avoid obscuring such concepts. The term “substantially” means that the associated parameter may not be exact as indicated but accounts for some variation due to specified tolerances.

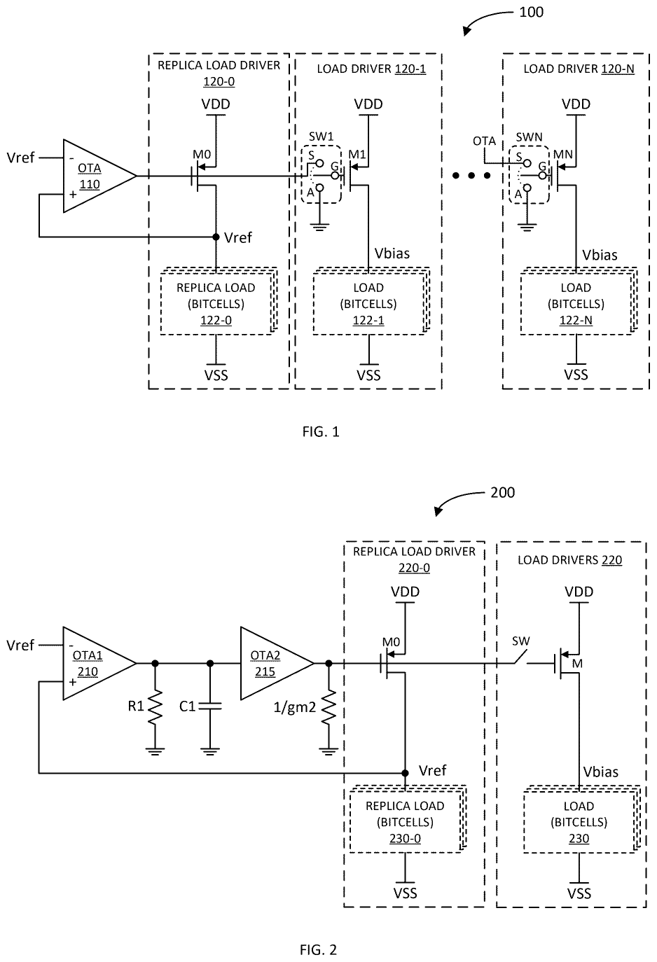

FIG. 1 illustrates a block diagram of an example load (e.g., memory) driving circuit 100 in accordance with an aspect of the disclosure. The load driving circuit 100 includes an operational transconductance amplifier (OTA) 110, a replica load driver 120-0, and a set of load drivers 120-1 to 120-N. The OTA 110 includes a first (e.g., negative) input configured to receive a reference voltage Vref, a second (e.g., positive) input, and an output.

The replica load driver 120-0 includes a p-channel field effect transistor (PFET) M0 coupled in series with a replica load 122-0 (e.g., a set of replica bitcells or memory cells) between an upper voltage rail VDD and a lower voltage rail VSS (e.g., ground). That is, the PFET M0 includes a source coupled to the upper voltage rail VDD, a gate coupled to the output of the OTA 110, and a drain coupled to the second (e.g., positive) input of the OTA 110. The replica load 122-0 is coupled between the drain of the PFET M0 and the lower voltage rail VSS.

The set of load drivers 120-1 to 120-N includes a set of switching devices SW1 to SWN and a set of PFETs M1 to MN, respectively. That is, the set of PFETs M1 to MN are coupled in series with the set of loads (e.g., bitcells or memory cells) 122-1 to 122-N between the upper voltage rail VDD and the lower voltage rail VSS, respectively. That is, the set of PFETs M1 to MN include respective sources coupled to the upper voltage rail VDD. The set of loads 122-1 to 122-N are coupled between drains of the set of PFETs M1 to MN and the lower voltage rail VSS, respectively.

The set of switching devices SW1 to SWN, which may each be implemented as a single-pole-double-throw (SPDT) switching device, include a set of pole terminals (G), a first set of throw terminals (S), and a second set of throw terminals (A), respectively. The pole terminals (G) of the set of switching devices SW1 to SWN are coupled to gates of the set of PFETs M1 to MN, respectively. The first set of throw terminals (S) are coupled to the output of the OTA 110. The second set of throw terminals (A) are coupled to the lower voltage rail VSS and/or ground.

The set of loads (e.g., bitcells) 122-1 to 122-N may be set to an active (A) (e.g., operational) mode or a sleep (S) (e.g., low power) mode. One solution for selectively setting the loads (e.g., bitcells) 122-1 to 122-N between active (A) mode or sleep (S) mode is to fully turn on or off the corresponding PFET, respectively. This may be accomplished by coupling the gate(s) of the PFET(s) associated with the selected load(s) (e.g., bitcell(s)) to the lower voltage rail VSS or ground (e.g., turning on the corresponding PFET) to set the selected load(s) to active (A) mode, or to the upper voltage rail VDD (e.g., turning off the corresponding PFET) to set the selected load(s) to sleep (S) mode. A drawback of this approach is that data stored in the selected bitcells may be lost during sleep (S) mode, which may require storing the data elsewhere prior to placing the bitcells in sleep (S) mode, and then rewriting the data back into the selected bitcells when it is needed. The process of storing the data elsewhere and rewriting the data back into the selected bitcells may consume more power than simply maintaining the bitcells in active (A) mode.

Another solution for selectively setting loads (e.g., bitcells) 122-1 to 122-N between active (A) mode or sleep (S) mode is to lower the supply voltage VDD associated with the selected load(s) (e.g., bitcells). This approach is sometimes referred to as Automatic Power Modulation (APM). A drawback of this approach is that to access the selected loads (e.g., bitcells) after being placed in sleep (S) mode, the supply voltage VDD has to be brought up, which causes charging of the selected (e.g., bitcells), which consumes power.

Accordingly, the approach shown in the example of FIG. 1 is referred to as Voltage Data Reduction (VDR), where the set of PFETs M1 and MN are operated as current sources instead of switches. With regard to active (A) mode, a selected subset of the loads (e.g., bitcells) 122-1 to 122-N may be placed in active (A) mode by coupling the gates of the selected PFETs M1 to MN to the lower voltage rail VSS or ground via the switching devices SW1 to SWn to fully turn on the selected PFETs M1 to MN, respectively. In active (A) mode, the voltage Vbias provided to the selected subset of loads (e.g., bitcells) is substantially the supply voltage at the upper voltage rail VDD (e.g., Vbias=VDD).

With regard to sleep (S) mode, a selected subset of the loads (e.g., bitcells) 122-1 to 122-N may be placed in sleep (S) mode by coupling the gates of the selected PFETs M1 to MN to the output of the OTA 110 via the switching devices SW1 to SWN to control the selected PFETs M1 to MN as current sources, respectively. Through feedback operation with respect to the replica load driver 120-0, which causes the replica load (e.g., replica bitcells) 122-0 to receive a bias voltage substantially equal to the reference voltage Vref, the selected subset of the loads (e.g.., bitcells) 122-1 to 122-N placed in sleep (S) mode receive a bias voltage Vbias being substantially equal to the reference voltage (e.g., Vbias=Vref). The reference voltage Vref is selected to cause the corresponding PFETs to generate a small amount of current to save power during sleep (S) mode, while providing a bias voltage Vbias to the selected subset of the loads (e.g., bitcells) 122-1 to 122-N to retain the data.

Further, in accordance with sleep (S) mode, the biasing of the selected PFETs M1 to MN also accounts for variation in process voltage temperature (PVT). This is because the replica load driver 120-0 is affected in substantially the same manner as the set of load drivers 120-1 to 120-N with variation in PVT. Thus, for different process corners, the reference voltage Vref and the bias voltage Vbias in sleep (S) mode vary substantially the same. Similarly, with variation in the supply voltage VDD, the reference voltage Vref and the bias voltage Vbias in sleep (S) mode vary substantially the same. Likewise, for variation in the temperature, the reference voltage Vref and the bias voltage Vbias in sleep (S) mode vary substantially the same.

An issue with the load (e.g., memory) driving circuit 100 is that switching between active (A) mode and sleep (S) mode for a large set of loads (e.g., bitcells) typically produces large transients. For example, when switching a large set of loads (e.g., bitcells) from active (A) mode to sleep (S) mode, a large rising current transient is produced as more PFETs are coupled to the output of the OTA 110. Conversely, when switching a large set of loads (e.g., bitcells) from sleep (S) mode to active (M) mode, a large falling current transient is produced as more PFETs are decoupled from the output of the OTA 110. These transients may destabilize the control loop effectuated by the OTA 110 and the replica load driver 120-0.

FIG. 2 illustrates a block diagram of another example load (e.g., memory) driving circuit 200 in accordance with another aspect of the disclosure. The load (e.g., memory) driving circuit 200 is similar to that of load (e.g., memory) driving circuit 100 including a replica driver 220-0, and a set of load drivers, collectively identified with reference number 220, including a set of switching devices SW, and a set of PFETs M coupled to a set of loads (e.g., bitcells) 230, as previously discussed. In contrast, the bias voltage Vbias control circuit of load (e.g., memory) driving circuit 200 is different than the bias voltage Vbias control circuit of load (e.g., memory) driving circuit 100.

More specifically, the bias voltage Vbias control circuit of load (e.g., memory) driving circuit 200 includes a first operational transconductance amplifier (OTA1) 210 cascaded with a second OTA2 215. The bias voltage Vbias control circuit may further include a shunt resistor R1 and a shunt capacitor C1 coupled to an output of the first OTA1 210 for loop stability (e.g., for setting the pole of the first OTA1 210). Similarly, the first OTA1 includes a first (e.g., negative) input configured to receive a reference voltage, a second (e.g., positive) input coupled to the node between the replica PFET M0 and the replica load (e.g., bitcells) 230-0. The output impedance of the second OTA2 215 is represented as a shunt resistor 1/gm2 coupled to the output of the second OTA2 215.

The first OTA1 210 provides the primary low frequency or pole control of the bias voltage Vbias. The second OTA2 215 deals with fast voltage/current transients generated by switching of the loads (e.g., bitcells) between active (A) mode and sleep (S) mode, as previously discussed. In this regards, it is preferred that the second OTA2 215 have a low output impedance 1/gm2 to source and sink the transient currents associated with the switching from active (A) mode to sleep (S) mode and switching from sleep (S) mode to active (A) mode, respectively. Further, it is also preferred that the pole of the second OTA2 215 is high enough in frequency that it does not encroach on the low frequency pole of the first OTA1 210.

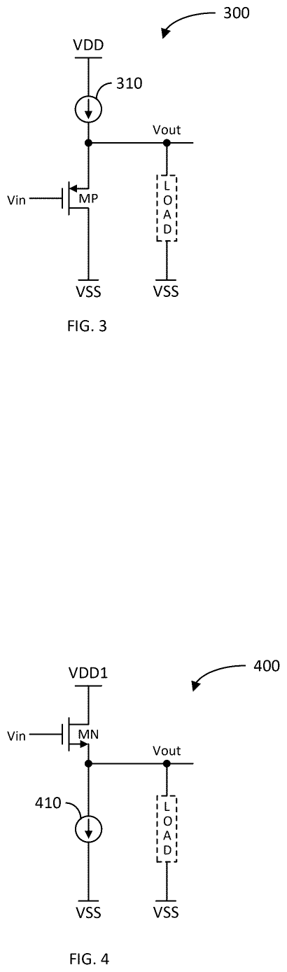

FIG. 3 illustrates a schematic diagram of an example PFET-based source follower (SF) 300 in accordance with another aspect of the disclosure. The source follower 300 may be an example implementation of the second OTA2 215 of load (e.g., memory) driving circuit 200.

In particular, the source follower 300 includes a current source 310 coupled in series with a PFET MP between an upper voltage rail VDD and a lower voltage rail VSS (e.g., ground). That is, the current source 310 is coupled between the upper voltage rail VDD and a source of the PFET MP. The PFET MP includes a gate configured to receive an input signal Vin (e.g., generated by the first OTA1 210), and a drain coupled to the lower voltage rail VSS. The source follower 300 is configured to generate an output signal (e.g., voltage) Vout (based on the input signal Vin) for applying to the gate of the replica PFET M0 and the gates of selected ones (in sleep mode (S)) of the set of PFETs M of load (e.g., memory) driving circuit 200 (represented as a load coupled between the output (e.g., at source of PFET MP) of the source follower 300 and the lower voltage rail VSS).

A drawback of the PFET-based source follower 300 is that it may be required to source a relatively large current (e.g., one (1) milli Amp (mA)), whereas a more practical current source 310 may supply a current of 10 micro Amps (μA). However, the PFET MP may be sized to sink a relatively large current (e.g., 1 mA). Thus, the source follower 300 may be practical to sink significant transient current, but not source significant transient current. Or said differently, the output impedance of the source follower 300 is relatively high for sourcing current and relatively low for sinking current. As previously discussed, it is desirable for the source follower to have a low output impedance such that its pole does not encroach on the pole of the first OTA1 210 of load (e.g., memory) driving circuit 200.

FIG. 4 illustrates a schematic diagram of another example NFET-based source follower (SF) 400 in accordance with another aspect of the disclosure. The source follower 400 may be an example implementation of the second OTA2 215 of load (e.g., memory) driving circuit 200.

In particular, the source follower 400 includes an n-channel field effect transistor (NFET) MN coupled in series with a current source 410 between an upper voltage rail VDD1 and a lower voltage rail VSS (e.g., ground). That is, the NFET MN includes a drain coupled to the upper voltage rail VDD1, and a gate configured to receive an input signal (e.g., voltage) Vin (e.g., generated by the first OTA1 210). The source follower 400 is configured to generate an output signal (e.g., voltage) Vout (based on the input signal Vin) for applying to the gate of the replica PFET M0 and the gates of selected ones (e.g., in sleep (S) mode) of the set of PFETs M of load (e.g., memory) driving circuit 200 (represented as a load coupled between the output (e.g., at the source of NFET MN) of the source follower 400 and the lower voltage rail VSS).

A drawback of the NFET-based source follower 400 is that it needs a lot of headroom to suitably operate, which may require a supply voltage VDD1 higher than the supply voltage VDD provided to the replica load driver 220-0 and set of load drivers 220 (e.g., VDD1>VDD). A consequence of this drawback is that the higher supply voltage VDD1 may require overvoltage protection for the NFET MN and the current source 410, which may the circuitry of the NFET-based source follower 400.

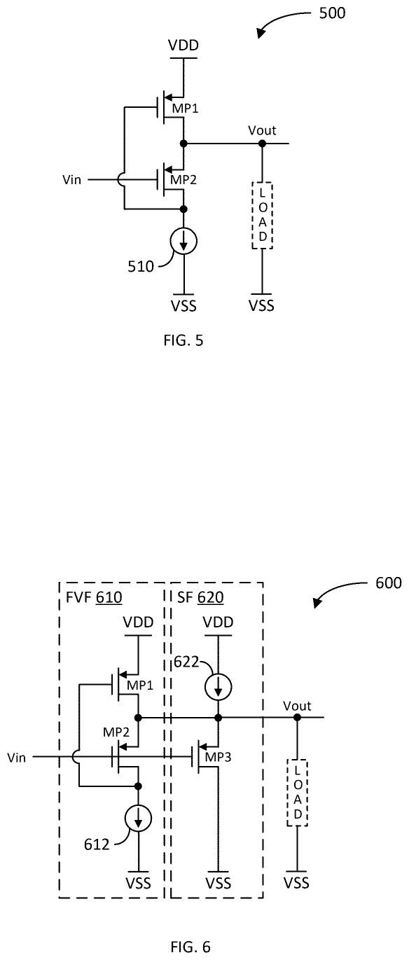

FIG. 5 illustrates a schematic diagram of an example PFET-based flipped voltage follower (FVF) 500 in accordance with another aspect of the disclosure. The PFET-based FVF 500 may be an example implementation of the second OTA2 215 of load (e.g., memory) driving circuit 200.

In particular, the PFET-based FVF 500 includes a first PFET MP1, a second PFET MP2, and a current source 510 coupled in series between an upper voltage rail VDD and a lower voltage rail VSS (e.g., ground). That is, the first PFET MP1 includes a source coupled to the upper voltage rail VDD, a gate coupled to a drain of the second PFET MP2, and a drain coupled to a source of the second PFET MP2. The second PFET MP2 includes a gate configured to receive an input signal (e.g., voltage) Vin. The current source 510 is coupled between the drain of the second PFET MP2 and the lower voltage rail VSS. The PFET-based FVF 500 is configured to generate an output signal (e.g., voltage) Vout (based on the input signal Vin) for applying to the gate of the replica PFET M0 and the gates of selected ones (e.g., in sleep (S) mode) of the set of PFETs M of load (e.g., memory) driving circuit 200 (represented as a load coupled between the output (e.g., at the drain and source of the PFETs MP1 and MP2, respectively) of the PFET-based FVF 500 and the lower voltage rail VSS).

A drawback of the PFET-based FVF 500 is that it may be required to sink a relatively large current (e.g., 1 mA), whereas a more practical current source 510 may sink a current of 10 μA. However, via a relatively large gain provided by the feedback loop configuration of the first PFET MP1 and the second PFET MP2 (e.g., the drain of the second PFET MP2 coupled to the gate of the first PFET MP1), the PFET-based FVF 500 may be able to source a relatively large current (e.g., 1 mA). Thus, the PFET-based FVF 500 may be practical to source significant transient current, but not sink significant transient current. Or said differently, the output impedance of the PFET-based FVF 500 is relatively low for sourcing current and relatively high for sinking current.

FIG. 6 illustrates a schematic diagram of an example load driver amplifier 600 in accordance with another aspect of the disclosure. The load driver amplifier 600 may be an example implementation of the second OTA2 215 of load (e.g., memory) driving circuit 200. The load driver amplifier 600 includes a PFET-based flipped voltage follower (FVF) 610 coupled in parallel with a PFET-based source follower (SF) 620 between an upper voltage rail VDD and a lower voltage rail VSS (e.g., ground).

In particular, the PFET-based FVF 610 includes a first PFET MP1, a second PFET MP2, and a first current source 612 coupled in series between the upper voltage rail VDD and the lower voltage rail VSS. That is, the first PFET MP1 includes a source coupled to the upper voltage rail VDD, a gate coupled to a drain of the second PFET MP2, and a drain coupled to a source of the second PFET MP2. The second PFET MP2 includes a gate configured to receive an input signal (e.g., voltage) Vin. The first current source 612 is coupled between the drain of the second PFET MP2 and the lower voltage rail VSS.

The PFET-based source follower 620 includes a second current source 622 coupled in series with a third PFET MP3 between the upper voltage rail VDD and the lower voltage rail VSS. That is, the second current source 622 is coupled between the upper voltage rail VDD and a source of the third PFET MP3. The source of the third PFET MP3 is coupled to the drain of the first PFET MP1 and the source of the second PFET MP2, all of which serve as an output of the load driver amplifier 600. The third PFET MP3 includes a gate coupled to the gate of the second PFET MP2 (also configured to receive the input signal Vin). The third PFET MP3 includes a drain coupled to the lower voltage rail VSS.

The load driver amplifier 600 is configured to generate an output signal (e.g., voltage) Vout (based on the input signal) for driving a load (e.g., the gate of the replica PFET M0 and gates of selected ones (e.g., in sleep (S) mode) of the set of PFETs M of load (e.g., memory) driving circuit 200 (represented as a load coupled between the output of the load driver amplifier 600 and the lower voltage rail VSS).

The load driver amplifier 600 exhibits the benefits of both the PFET-based FVF 610 and the PFET-based source follower 620. That is, via its relatively large gain provided by the feedback loop configuration of the first PFET MP1 and the second PFET MP2 (e.g., the drain of the second PFET MP2 is coupled to the gate of the first PFET MP1), the PFET-based FVF 610 may be able to source a relatively large current (e.g., 1 mA). With regard to the PFET-based source follower 620, the third PFET MP3 may be sized to sink a relatively large current (e.g., 1 mA). Thus, the PFET-based source follower 620 may be practical to sink significant transient current. In summary, the output impedance of the load driver amplifier 600 is relatively low for both sourcing and sinking current. This is highly desirable as the low output impedance results in a pole for the load driver amplifier 600 that may not encroach on the pole of the first OTA1 210 of load (e.g., memory) driving circuit 200.

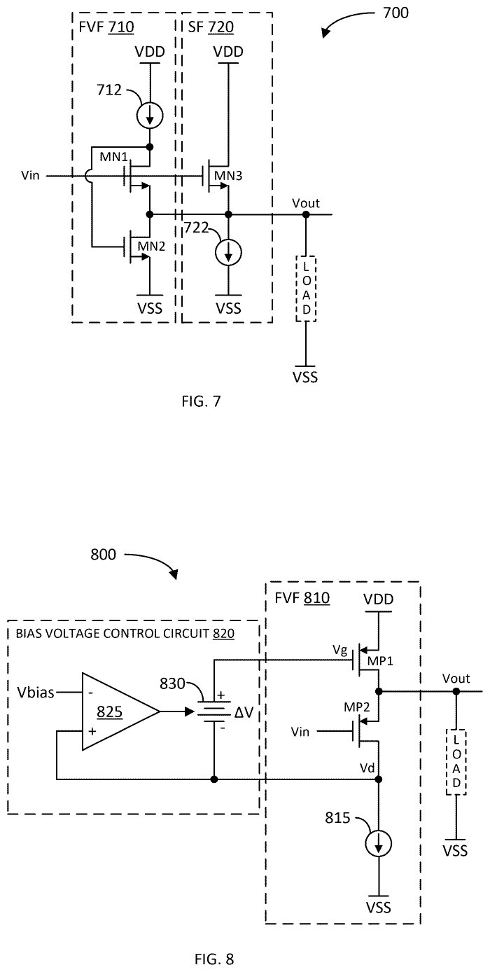

FIG. 7 illustrates a schematic diagram of another example load driver amplifier 700 in accordance with another aspect of the disclosure. The load driver amplifier 700 may be an NFET version of the load driver amplifier 600. The load driver amplifier 700 includes an NFET-based flipped voltage follower (FVF) 710 coupled in parallel with an NFET-based source follower (SF) 720 between an upper voltage rail VDD and a lower voltage rail VSS (e.g., ground).

In particular, the NFET-based FVF 710 includes a first current source 712, a first NFET MN1, and a second NFET MN2 coupled in series between the upper voltage rail VDD and the lower voltage rail VSS. That is, the first current source 712 is coupled between the upper voltage rail VDD and the drain of the first NFET MN1. The drain of the first NFET MN1 is coupled to a gate of the second NFET MN2 to effectuate a feedback loop configuration. The first NFET MN1 includes a gate configured to receive an input signal (e.g., voltage) Vin. The first NFET MN1 includes a source coupled to a drain of the second NFET MN2. The second NFET MN2 includes a source coupled to the lower voltage rail VSS.

The source follower 720 includes a third NFET MN3 coupled in series with a second current source 722 between the upper voltage rail VDD and the lower voltage rail VSS. That is, the third NFET MN3 includes a drain coupled to the upper voltage rail VDD. The third NFET MN3 includes a gate coupled to the gate coupled of the first NFET MN1 (also configured to receive the input signal Vin). The third NFET MN3 includes a source coupled to the source of the first NFET MN1 and the drain of the second NFET MN2, all of which serve as an output of the load driver amplifier 700. The second current source 722 is coupled between the output of the load driver amplifier 700 and the lower voltage rail VSS. A load may be coupled between the output of the load driver amplifier 700 and the lower voltage rail VSS.

The load driver amplifier 700 exhibits the benefits of both the NFET-based FVF 710 and the NFET-based source follower 720. That is, via its relatively large gain provided by the loop configuration of the first NFET MN1 and the second NFET MN2 (e.g., the drain of the first NFET MN1 is coupled to the gate of the second NFET MN2), the NFET-based FVF 710 may be able to sink a relatively large current (e.g., 1 mA). With regard to the NFET-based source follower 720, the third NFET MN3 may be sized to source a relatively large current (e.g., 1 mA). Thus, the NFET-based source follower 720 may be practical to source significant transient current. In summary, the output impedance of the load driver amplifier 700 is relatively low for both sourcing and sinking current.

FIG. 8 illustrates a schematic diagram of an example load driver amplifier 800 in accordance with another aspect of the disclosure. The load driver amplifier 800 includes a modified PFET-based flipped voltage follower (FVF) 810 and a bias voltage control circuit 820. Although not shown, a source follower may be coupled in parallel with the modified PFET-based FVF 810 as in load driver amplifier 600.

The modified PFET-based FVF 810 includes a first PFET MP1, a second PFET MP2, and a current source 815, all coupled in series between an upper voltage rail VDD and a lower voltage rail VSS. That is, the first PFET MP1 includes a source coupled to an upper voltage rail VDD and a drain coupled to a source of the second PFET MP2. The source of the first PFET MP1 and the drain coupled of the second PFET MP2 serve as an output of the modified PFET-based FVF 810. The second PFET MP2 includes a gate configured to receive an input signal (e.g., voltage) Vin. The current source 815 is coupled between a drain of the second PFET MP2 and the lower voltage rail VSS. The modified PFET-based FVF 810 is configured to generate an output signal (e.g., voltage) Vout (based on the input signal Vin) at the output of the modified PFET-based FVF 810. As shown, a load may be coupled between the output of the modified PFET-based FVF 810 and the lower voltage rail VSS.

With further reference to FIG. 5, a headroom issue with the PFET-based FVF 500 may occur if the supply voltage VDD decreases too low. In the case where the PVT corner associated with the PFET-based FVF 500 is fast-fast, high temperature, and low voltage (FFHTLV), the gate-to-source voltage Vgs of the first PFET MP1 may become too small, which results in the drain voltage Vd of the second PFET MP2 becoming too high. In such case, the drain-to-source voltage Vds of the second PFET MP2 decreases, which may cause the device to operate in the triode region, and not in the more desirable saturation region. In such situation, the high gain provided by the feedback configuration of the first and second PFETs MP1 and MP2 collapses causing the output impedance of the PFET-based FVF 500 becoming too high.

In the case where the PVT corner associated with the PFET-based FVF 500 is slow-slow, low temperature, and low voltage (SSLTLV), the gate-to-source voltage Vgs of the first PFET MP1 may be too high, which results in the drain voltage Vd of the NFET-based current source 510 becoming too low. In such a case, the drain-to-source voltage Vds of the NFET-based current source 815 becomes too small causing a significant decrease in the current generated by the current source 815. The low current may cause a collapse of the high-gain feedback loop configuration of the first and second PFETs MP1 and MP2 causing the output impedance of the PFET-based FVF 500 becoming too high.

Accordingly, the load driver amplifier 800 includes the bias voltage control circuit 820 to control the voltage Vd at the node between the second PFET MP2 and the NFET-based current source 815 so that both operate in the saturation region. In this regard, the bias voltage control circuit 820 includes an operational amplifier 825 including a first (e.g., negative) input configured to receive a target bias voltage Vbias, a second (e.g., positive) input coupled to the node between the second PFET MP2 and the NFET-based current source 815, and an output coupled to a control input of a variable voltage source 830. The variable voltage source 830 includes a positive terminal coupled to the gate of the first PFETs MP1, and a negative terminal coupled to the node between the second PFET MP2 and the NFET-based current source 815. As indicated, the target bias voltage Vbias is the target voltage for the voltage Vd at the node between the second PFET MP2 and the NFET-based current source 815.

In operation, if the bias voltage control circuit 820 senses that the voltage Vd is greater than the bias voltage Vbias (which may cause the second PFET MP2 to operate in the triode region), the operational amplifier 825 generates a control signal at its output (coupled to the control input of the variable voltage source 830) to increase the voltage difference ΔV generated by the variable voltage source 830 to cause a decrease in the voltage Vd such that it becomes substantially equal to the bias voltage Vbias. This maintains the second PFET MP2 operating in the saturation region.

Similarly, if the bias voltage control circuit 820 senses that the voltage Vd is less than the bias voltage Vbias (which may cause the NFET-based current source 815 to significantly decrease its current), the operational amplifier 825 generates a control signal at its output (coupled to the control input of the variable voltage source 830) to decrease the voltage difference ΔV generated by the variable voltage source 830 to cause an increase the voltage Vd such that it becomes substantially equal to the bias voltage Vbias. This maintains the NFET-based current source 815 generating the needed current so as not to cause a collapse of the high-gain provided by the feedback loop configuration of the PFETs MP1 and MP2.

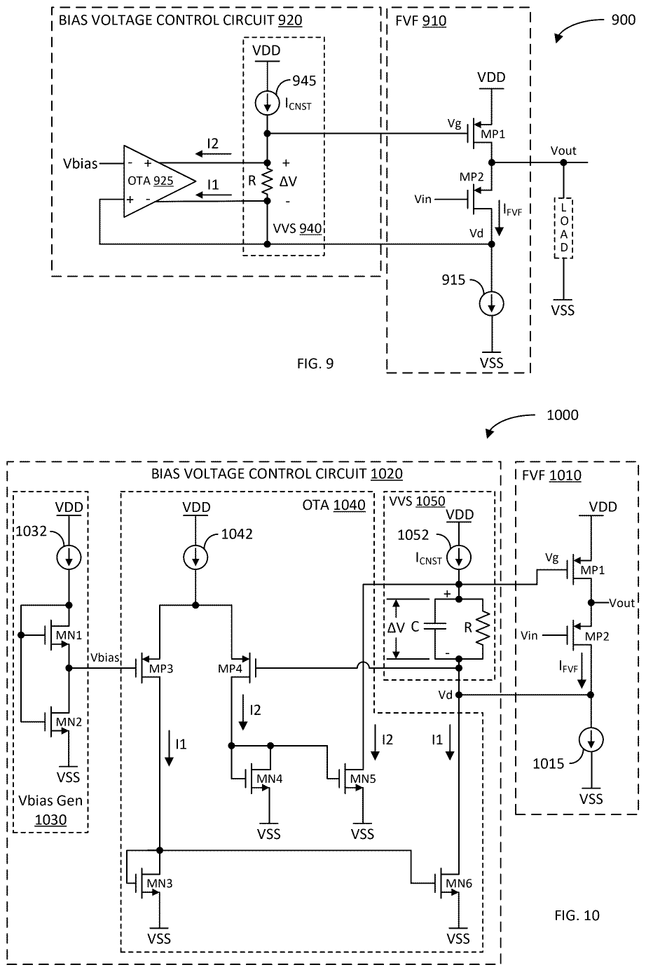

FIG. 9 illustrates a schematic diagram of another example load driver amplifier 900 in accordance with another aspect of the disclosure. The load driver amplifier 900 may be an example more detail implementation of the load driver amplifier 800. Accordingly, the load driver amplifier 900 includes a modified PFET-based flipped voltage follower (FVF) 910 and a bias voltage control circuit 920. The modified PFET-based FVF 910 is similar to the modified PFET-based FVF 810 of load driver amplifier 800, including PFETs MP1-MP2 and current source 915 in the same arrangement. Although not shown, a source follower may be coupled in parallel with the modified PFET-based FVF 910 as in load driver amplifier 600.

The bias voltage control circuit 920 includes an operational transconductance amplifier (OTA) 925 and a variable voltage source (VVS) 940. The OTA 925 includes a first (e.g., negative (−)) input configured to receive a target bias voltage Vbias for controlling the voltage Vd at the node between the second PFET MP2 and the NFET-based current source 915. The OTA 925 also includes a second (e.g., positive (+)) input coupled to the node between the second PFET MP2 and the NFET-based current source 915. The OTA 925 further includes a first (e.g., negative (−)) output and a second (e.g., positive (+)) output.

The variable voltage source (VVS) 940 includes a current source 945 and a resistor R coupled in series between an upper voltage rail VDD and the node between the second PFET MP2 and the NFET-based current source 915. The current source 945 is configured to generate a substantially constant current I_{CNST}. The second (+) output of the OTA 925 is coupled to a node between the current source 945 and the resistor R, which is also coupled to the gate of the first PFET MP1. The first (−) output of the OTA 925 is coupled to the node between the second PFET MP2 and the NFET current source 915.

In operation, if the OTA 925 senses that the voltage Vd is greater than the bias voltage Vbias (which may cause the second PFET MP2 to operate in the triode region), the OTA 925 increases a first current I1 drawn from the current source I_{CNST} into the first (−) output of the OTA 925 via the resistor R, which consequently decreases a second current I2 drawn directly from the current source 945 into the second (+) output of the OTA 925 (e.g., to substantially maintain the relationship of I1+I2=I_{CNST}). The increase in the first current I1 increases a voltage drop ΔV across the resistor R, which decreases the voltage Vd such that it becomes substantially equal to the bias voltage Vbias. This maintains the second PFET MP2 operating in the saturation region.

Similarly, if the OTA 925 senses that the voltage Vd is less than the bias voltage Vbias (which may cause the NFET-based current source 915 to significantly decrease its current), the OTA 925 increases the second current I2 drawn directly from the current source I_{CNST} into the second (+) output of the OTA 925, which consequently decreases the first current I1 drawn from the current source 945 via the resistor R into the first (−) output of the OTA 925 (e.g., to substantially maintain the relationship of I1+I2=I_{CNST}). The decrease in the first current I1 decreases the voltage drop ΔV across the resistor R, which increases the voltage Vd such that it becomes substantially equal to the bias voltage Vbias. This maintains the NFET-based current source 915 operating in the saturation region.

The NFET-based current source 915 of the modified PFET-based FVF 910 may be configured to generate a current I_{FVF} substantially equal to the constant current I_{CNST} generated by the current source 945. Accordingly, the current I_{FVF} through the modified PFET-based FVF 910 may also be substantially equal to the sum of the first current I1 and the second current I2 (e.g., I_{FVF}=I1+I2).

FIG. 10 illustrates a schematic diagram of another example load driver amplifier 1000 in accordance with another aspect of the disclosure. The load driver amplifier 1000 may be an example more detail implementation of the load driver amplifier 800 or 900.

Accordingly, the load driver amplifier 1000 includes a modified PFET-based flipped voltage follower (FVF) 1010 and a PFET-based bias voltage control circuit 1020. The modified PFET-based FVF 1010 is similar to the modified PFET-based FVF 810 or 910 of load driver amplifier 800 or 900, including PFETs MP1-MP2 and current source 1015 in the same arrangement. Although not shown, a source follower may be coupled in parallel with the FVF 1010 as in load driver amplifier 600.

The PFET-based bias voltage control circuit 1020 includes a target bias voltage (Vbias) generator 1030, an operational transconductance amplifier (OTA) 1040, and a variable voltage source (VVS) 1050. The bias voltage generator 1030 includes a current source 1032, a first NFET MN1, and a second NFET MN2, all coupled in series between an upper voltage rail VDD and a lower voltage rail VSS. That is, the current source 1032 is coupled between the upper voltage rail and the drain/gate of the first NFET MN1 and the gate of the second NFET MN2. The first NFET MN1 includes a source coupled to a drain of the second NFET MN2. The second NFET MN2 includes a source coupled to the lower voltage rail VSS. The bias voltage generator 1030 is configured to generate the target bias voltage Vbias at the drain/source (output) of the NFETs MN1/MN2.

The OTA 1040 includes a current source 1042, input differential PFETs MP3-MP4, and NFETs MN3-MN6. The current source 1042 is coupled between the upper voltage rail VDD and the respective sources of the input differential PFETs MP3-MP4. The input differential PFET MP3 includes a gate (e.g., first (−) input of the OTA 1040) coupled to the output of the bias voltage generator 1030. The input differential PFET MP4 includes a gate (e.g., second (+) input of the OTA 1040) coupled to the node between the second PFET MP2 and the NFET-based current source 1015. The input differential PFET MP3 includes a drain coupled to drain and gate of NFET MN3 and gate of NFET MN6. The input differential PFET MP4 includes a drain coupled to drain and gate of NFET MN4 and gate of NFET MN5. The NFET MN5 includes a drain (e.g., second (+) output of the OTA 1040) coupled to the gate of the first PFET MP1. The NFET MN6 includes a drain (e.g., first (−) output of the OTA 1040) coupled to the node between the second PFET MP2 and the NFET-based current source 1015. The NFETs MN3-MN6 include sources coupled to the lower voltage rail VSS.

The variable voltage source (VVS) 1050 includes a current source 1052 coupled in series with a parallel-coupled resistor R and capacitor C (R-C) between the upper voltage rail VDD and the node between the second PFET MP2 and the NFET-based current source 1015 (e.g., also the first (−) output of the OTA 1040). The node between the current source 1052 and the parallel-coupled R-C is coupled to the gate of the first PFET MP1 and the drain (e.g., second (+) output of the OTA 1040) of the NFET MN5. The current source 1052 is configured to generate a substantially constant current I_{CNST}.

In operation, if the voltage Vd increases above the target bias voltage Vbias (which may cause the second PFET MP2 to operate in the triode region), the input differential PFET MP3 is turned on more than the input differential PFET MP4. Accordingly, the first current I1 through the input differential PFET MP3 is greater than the second current I2 through the input differential PFET MP4. The first current I1 is mirrored to flow through the NFET MN6 via the current mirror coupling of the NFETs MN3 and MN6. The larger first current I1 flows through the resistor R (e.g., into the first (−) output (drain of NFET MN6) of the OTA 1040) to produce a greater voltage drop ΔV across the resistor R. This causes the voltage Vd to decrease until it becomes substantially equal to the target bias voltage Vbias (e.g., where I1=I2, and I1+I2=I_{CNST}). This maintains the second PFET MP2 operating in the saturation region.

Similarly, if the voltage Vd decreases below the bias voltage Vbias (which may cause the NFET-based current source 1015 to significantly decrease its current), the input differential PFET MP4 is turned on more than the input differential PFET MP3. Accordingly, the second current I2 through the input differential PFET MP4 is greater than the first current I1 through the input differential PFET MP3. The second current I2 is mirrored to flow through the NFET MN5 via the current mirror coupling of the NFETs MN4 and MN5. The larger second current I2 (e.g., drawn into the second (+) output (drain of NFET MN5) decreases the first current I1 until it becomes substantially equal to the target bias voltage Vbias (e.g., where substantially I1=I2, and I1+I2=I_{CNST}). This maintains the NFET-based current source 1015 generating the needed current to maintain the high-gain provided by the feedback loop configuration of the PFETs MP1-MP2.

Similarly, the NFET-based current source 1015 of the modified PFET-based FVF 1010 may be configured to generate a current substantially equal to the constant current I_{CNST} generated by the current source 1052. Accordingly, the current I_{FVF} through the modified PFET-based FVF 1010 may also be substantially equal to the sum of the first current I1 and the second current I2 (e.g., I_{FVF}=I1+I2). As a final note, the capacitor C in parallel with the resistor R provides a pole to stabilize the control operation of the bias voltage control circuit 1020. The following describes NFET-based versions of the load driver amplifiers 800, 900, and 1000, respectively.

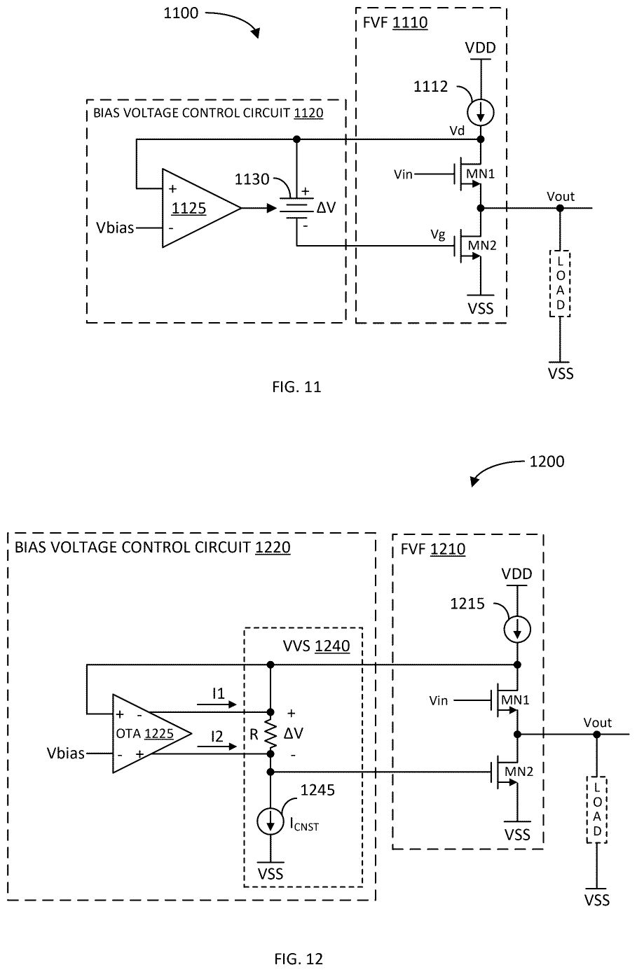

FIG. 11 illustrates a schematic diagram of an example load driver amplifier 1100 in accordance with another aspect of the disclosure. The load driver amplifier 1100 includes a modified NFET-based flipped voltage follower (FVF) 1110 and a bias voltage control circuit 1120. Although not shown, a source follower may be coupled in parallel with the modified NFET-based FVF 1110 as in load driver amplifier 700.

The modified NFET-based FVF 1110 includes a current source 1112, a first NFET MN1, a second NFET MN2, all coupled in series between an upper voltage rail VDD and a lower voltage rail VSS. That is, the current source 1112 is coupled between the upper voltage rail VDD and a drain of the first NFET MN1. The first NFET MN1 includes a gate configured to receive an input signal (e.g., voltage) Vin. The first NFET MN1 includes a source coupled to a drain of the second NFET MN2, where the source of the first NFET MN1 and the drain of the second NFET MN2 serve as an output of the modified PFET-based FVF 1110. The second NFET MP2 includes source coupled to the lower voltage rail VSS. The modified NFET-based FVF 1110 is configured to generate an output signal (e.g., voltage) Vout based on the input signal Vin. As shown, a load may be coupled between the output of the modified NFET-based FVF 1110 and the lower voltage rail VSS.

The bias voltage control circuit 1120 is configured to control the voltage Vd at the node between the PFET-based current source 1112 and the first NFET MN1 so that both operate in the saturation region. In this regard, the bias voltage control circuit 1120 includes an operational amplifier 1125 including a first (e.g., negative) input configured to receive a target bias voltage Vbias, a second (e.g., positive) input coupled to the node between the PFET-based current source 1112 and the first NFET MN1, and an output coupled to control input of a variable voltage source 1130. The variable voltage source 1130 includes a positive terminal coupled to the node between the PFET-based current source 1112 and the first NFET MN1, and a negative terminal coupled to the gate of the second NFET MN2. As indicated, the target bias voltage Vbias is the target voltage for voltage Vd at the node between the PFET-based current source 1112 and the first NFET MN1.

In operation, if the bias voltage control circuit 1120 senses that the voltage Vd is less than the target bias voltage Vbias (which may cause the first NFET MN1 to operate in the triode region), the operational amplifier 1125 generates a control signal at its output (e.g., control input of the variable voltage source 1130) to increase the voltage difference ΔV generated by the variable voltage source 1130 to cause an increase in the voltage Vd such that it becomes substantially equal to the target bias voltage Vbias. This maintains the first NFET MN1 operating in the saturation region.

Similarly, if the bias voltage control circuit 1120 senses that the voltage Vd is greater than the target bias voltage Vbias (which may cause the PFET-based current source 1115 to significantly decrease its current), the operational amplifier 1125 generates a control signal at its output (e.g., the control input of the variable voltage source 1130) to decrease the voltage difference ΔV generated by the variable voltage source 1130 to cause a decrease in the voltage Vd such that it becomes substantially equal to the target bias voltage Vbias. This maintains the PFET-based current source 1115 generating the needed current so as not to cause a collapse of the high-gain provided by the feedback loop configuration of the NFETs MN1 and MN2.

FIG. 12 illustrates a schematic diagram of another example load driver amplifier 1200 in accordance with another aspect of the disclosure. The load driver amplifier 1200 may be an example more detail implementation of the load driver amplifier 1100. Accordingly, the load driver amplifier 1200 includes a modified NFET-based flipped voltage follower (FVF) 1210 and a bias voltage control circuit 1220. The modified NFET-based FVF 1210 is similar to the modified NFET-based FVF 1110 of load driver amplifier 1100, including current source 1215 and NFETs MN1-MN2 in the same arrangement. Although not shown, a source follower may be coupled in parallel with the FVF 1210 as in load driver amplifier 700.

The bias voltage control circuit 1220 includes an operational transconductance amplifier (OTA) 1225 and a variable voltage source (VVS) 1240. The OTA 1225 includes a first (e.g., negative (−)) input configured to receive a target bias voltage Vbias for controlling the voltage Vd at the node between the PFET-based current source 1215 and the first NFET MN1. The OTA 1225 also includes a second (e.g., positive (+)) input coupled to the node between the PFET-based current source 1215 and the first NFET MN1. The OTA 1225 further includes a first (e.g., negative (−)) output and a second (e.g., positive (+)) output.

The variable voltage source (VVS) 1240 includes a current source 1245 and a resistor R coupled in series between an upper voltage rail VDD and the gate of the second NFET MN2. The current source 1245 is configured to generate a substantially constant current I_{CNST}. The first (−) output of the OTA 1225 is coupled to the node between the PFET-based current source 1215 and the first NFET MN1. The second (+) output of the OTA 1225 is coupled to the gate of the second NFET MN2, which is also coupled to the node between the resistor R and the current source 1245.

In operation, if the OTA 1225 senses that the voltage Vd is less than the target bias voltage Vbias (which may cause the first NFET MN1 to operate in the triode region), the OTA 1225 increases a first current I1 supplied from the first (−) output through the resistor R, which consequently decreases a second current I2 supplied from the second (+) to the current source 1245 (e.g., to substantially maintain the relationship of I1+I2=I_{CNST}). The increase in the first current I1 increases a voltage drop ΔV across the resistor R, which increases the voltage Vd such that it becomes substantially equal to the target bias voltage Vbias. This maintains the first NFET MN1 operating in the saturation region.

Similarly, if the OTA 1225 senses that the voltage Vd is greater than the target bias voltage Vbias (which may cause the PFET-based current source 1215 to significantly decrease its current), the OTA 1225 decreases the first current I1 supplied from the first (−) output through the resistor R, which increases the second current I2 supplied from the second (+) output to the current source 1245 (e.g., to substantially maintain the relationship of I1+I2=I_{CNST}). The decrease in the first current I1 decreases the voltage drop ΔV across the resistor R, which decreases the voltage Vd such that it becomes substantially equal to the target bias voltage Vbias. This maintains the PFET-based current source 1215 operating in the saturation region.

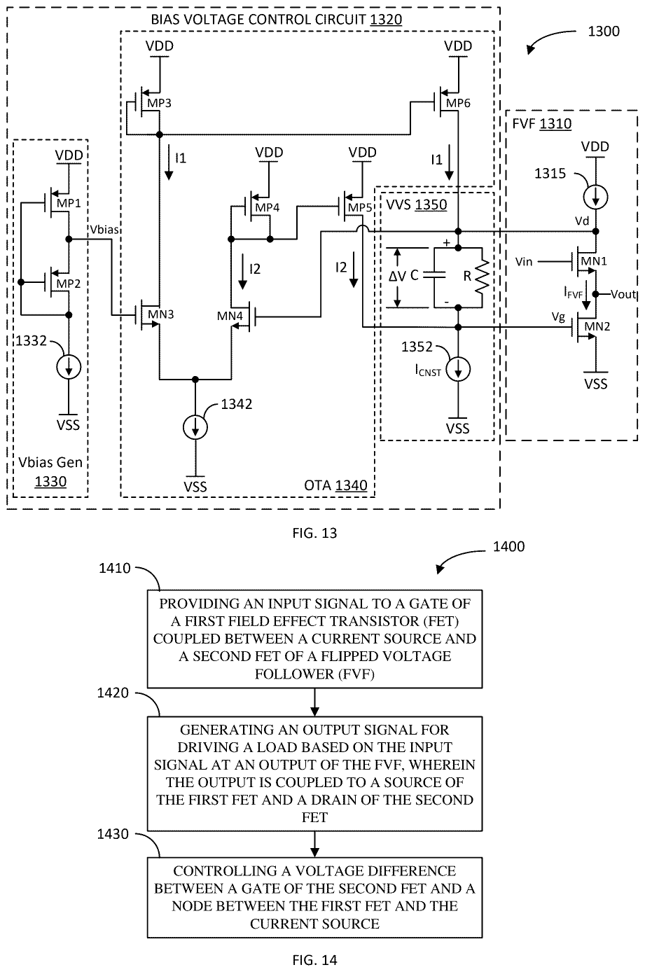

FIG. 13 illustrates a schematic diagram of another example load driver amplifier 1300 in accordance with another aspect of the disclosure. The load driver amplifier 1300 may be an example more detail implementation of the load driver amplifier 1100 or 1200.

Accordingly, the load driver amplifier 1300 includes a modified NFET-based flipped voltage follower (FVF) 1310 and an NFET-based bias voltage control circuit 1320. The modified NFET-based FVF 1310 is similar to the modified NFET-based FVF 1110 or 1210 of load driver amplifier 1100 or 1200, including current source 1315 and NFETs MN1-MN2 in the same arrangement. Although not shown, a source follower may be coupled in parallel with the modified NFET-based FVF 1310 as in load driver amplifier 700.

The NFET-based bias voltage control circuit 1320 includes a target bias voltage (Vbias) generator 1330, an operational transconductance amplifier (OTA) 1340, and a variable voltage source (VVS) 1350. The bias voltage generator 1330 includes a first PFET MP1, a second PFET MP2, and a current source 1332, all coupled in series between an upper voltage rail VDD and a lower voltage rail VSS. That is, the first PFET MP1 includes a source coupled to the upper voltage rail VDD. The first PFET MP1 includes a gate coupled to a gate and drain of the second PFET MP2. The first PFET MP1 includes a drain coupled to a source of the second PFET MP2. The bias voltage generator 1330 is configured to generate the target bias voltage Vbias at the drain/source (output) of the PFETs MP1/MP2.

The OTA 1340 includes a current source 1342, PFETs MP3-MP6, and input differential NFETs MN3-MN4. The PFET includes a source coupled to the upper voltage rail VDD, and gate and drain coupled to a drain of the input differential NFET MN3 and a gate of the PFET MP6. The PFET MP6 includes a source coupled to the upper voltage rail VDD, and a drain (e.g., first (−) output of the OTA 1340) coupled to the node between the PFET-based current source 1315 and the first NFET MN1. The input differential NFET MN3 includes a gate (e.g., first (−) input of the OTA 13400 coupled to the output of the bias voltage generator 1330 to receive the target bias voltage Vbias. The input differential NFET MN4 includes a gate (e.g., second (+) input of the OTA 1340) coupled to the node between the PFET-based current source 1315 and the first NFET MN1. The current source 1342 is coupled between the respective sources of the input differential NFETs MN3-MN4 and the lower voltage rail VSS. The PFET MP4 includes a source coupled to the upper voltage rail VDD, and gate and drain coupled to a drain of the input differential NFET MN4 and a gate of the PFET MP5. The PFET MP5 includes a source coupled to the upper voltage rail VDD and a drain (e.g., second (+) output of the OTA 1340) coupled to the gate of the second NFET MN2.

The variable voltage source (VVS) 1350 includes a parallel-coupled resistor R and capacitor C (R-C) coupled in series with a current source 1352 between a drain of PFET MP6 (e.g., first (−) output of the OTA 1340) and the lower voltage rail VSS. The node between the PFET MP6 and the parallel-coupled R-C is coupled to the node between the PFET-based current source 1315 and the first NFET MN1. The node between the current source 1052 and the parallel-coupled resistor-capacitor R-C is coupled to the gate of the second NFET MN2 and the drain (e.g., second (+) output of the OTA 1340) of the PFET MP5. The current source 1352 is configured to generate a substantially constant current I_{CNST}.

In operation, if the voltage Vd decreases below the target bias voltage Vbias (which may cause the first NFET MN1 to operate in the triode region), the input differential NFET MN3 is turned on more than the input differential NFET MN4. Accordingly, the first current I1 through the input differential NFET MN3 is greater than the second current I2 through the input differential NFET MN4. The first current I1 is mirrored to flow through the PFET MP6 via the current mirror coupling of the PFETs MP3 and MP6. The larger first current I1 flows through the resistor R to produce a greater voltage drop ΔV across the resistor R. This causes the voltage Vd to increase until it becomes substantially equal to the target bias voltage Vbias (e.g., where I1=I2, and I1+I2=I_{CNST}). This maintains the first NFET MN1 operating in the saturation region.

Similarly, if the voltage Vd increases below the bias voltage Vbias (which may cause the PFET-based current source 1315 to significantly decrease its current), the input differential NFET MN4 is turned on more than the input differential NFET MN3. Accordingly, the second current I2 through the input differential NFET MN4 is greater than the first current I1 through the input differential NFET MN3. The second current I2 is mirrored to flow through the PFET MP5 via the current mirror coupling of the PFETs MP4 and MP5. The larger second current I2 decreases the first current I1 to decrease the voltage drop ΔV across the resistor R until the voltage Vd becomes substantially equal to the target bias voltage Vbias (e.g., where substantially I1=I2, and I1+I2=I_{CNST}). This maintains the PFET-based current source 1315 generating the needed current to maintain the high-gain provided by the feedback loop configuration of the NFETs MN1-MN2.

Similarly, the PFET-based current source 1315 of the modified NFET-based FVF 1310 may be configured to generate a current substantially equal to the constant current I_{CNST} generated by the current source 1352. Accordingly, the current I_{FVF} through the modified NFET-based FVF 1310 may also be substantially equal to the sum of the first current I1 and the second current I2 (e.g., I_{FVF}=I1+I2). As a final note, the capacitor C in parallel with the resistor R provides a pole to stabilize the control operation of the bias voltage control circuit 1320.

FIG. 14 illustrates a flow diagram of an example method 1400 of driving a load in accordance with another aspect of the disclosure. The method 1400 includes providing an input signal to a gate of a first field effect transistor (FET) coupled between a current source and a second FET of a flipped voltage follower (FVF) (block 1410). The method 1400 further includes generating an output signal for driving the load based on the input signal at an output of the FVF, wherein the output is coupled to a source of the first FET and a drain of the second FET (block 1420). Additionally, the method 1400 includes controlling a voltage difference between a gate of the second FET and a node between the first FET and the current source (block 1430).

The following provides an overview of aspects of the present disclosure:
Aspect 1: An apparatus, comprising: a flipped voltage follower (FVF) including a first p-channel field effect transistor (PFET), a second PFET, and a first current source coupled in series between an upper voltage rail and a lower voltage rail; and a bias voltage control circuit coupled to a node between the second PFET and the first current source.
Aspect 2: The apparatus of aspect 1, wherein the bias voltage control circuit is configured to: receive a first voltage; and control a second voltage at the node between the second PFET and the first current source based on the first voltage.
Aspect 3: The apparatus of aspect 1 or 2, wherein the bias voltage control circuit comprises: an operational amplifier including a first input configured to receive the first voltage, a second input coupled to the node between the second PFET and the first current source, and an output; and a variable voltage source including a first terminal coupled to a gate of the first PFET, a second terminal coupled to the node between the second PFET and the first current source, and a control input coupled to the output of the operational amplifier.
Aspect 4: The apparatus of aspect 3, wherein the operational amplifier is configured to control the variable voltage source to control the second voltage at the node between the second PFET and the first current source based on the first voltage.
Aspect 5: The apparatus of aspect 1, wherein the bias voltage control circuit comprises: an operational transconductance amplifier (OTA) including a first input configured to receive a first voltage, a second input coupled to the node between the second PFET and the first current source, a first output coupled to the node between the second PFET and the first current source, and a second output coupled to a gate of the first PFET; and a variable voltage source comprising a second current source and a resistor, wherein the second current source is coupled between the upper voltage rail and the gate of the first PFET, and wherein the resistor is coupled between the gate of the first PFET and the node between the second PFET and the first current source.
Aspect 6: The apparatus of aspect 5, wherein the OTA, based on the first voltage, is configured to draw a first current into the first output from the second current source via the resistor and draw a second current into the second output directly from the second current source to control a second voltage at the node between the second PFET and the first current source.
Aspect 7: The apparatus of aspect 1, wherein the bias voltage control circuit comprises: a bias voltage generator including an output; an operational transconductance amplifier (OTA) including a first input coupled to the output of the bias voltage generator, a second input coupled to the node between the second PFET and the first current source, a first output coupled to the node between the second PFET and the first current source, and a second output coupled to a gate of the first PFET; and a variable voltage source including at least a portion coupled between the second output and the first output of the OTA.
Aspect 8: The apparatus of aspect 7, wherein the bias voltage generator comprises: a second current source; a first n-channel field effect transistor (NFET), wherein the second current source is coupled between the upper voltage rail and a drain and a gate of the first NFET; and a second NFET including a drain coupled to a source of the first NFET, a gate coupled to the gate and drain of the first NFET, and a source coupled to the lower voltage rail, wherein the source of the first NFET and the drain of the second NFET serve as the output of the bias voltage generator.
Aspect 9: The apparatus of aspect 7 or 8, wherein the OTA comprises: a first input differential PFET including a gate coupled to the output of the bias voltage generator; a second input differential PFET including a gate coupled to the node between the second PFET and the first current source; a second current source coupled between the upper voltage rail and respective sources of the first and second input differential PFETs; a first n-channel field effect transistor (NFET) including a drain and a gate coupled to a drain of the first input differential PFET, and a source coupled to the lower voltage rail; a second NFET including a drain coupled to the node between the second PFET and the first current source, a gate coupled to the gate and the drain of the first NFET, and a source coupled to the lower voltage rail; a third NFET including a drain and a gate coupled to a drain of the second input differential PFET, and a source coupled to the lower voltage rail; and a fourth NFET including a drain coupled to the gate of the first PFET, a gate coupled to the gate and the drain of the third NFET, and a source coupled to the lower voltage rail.
Aspect 10: The apparatus of any one of aspects 7-9, wherein the variable voltage source comprises: a second current source coupled between the upper voltage rail and the second output of the OTA; and a parallel-coupled resistor and capacitor coupled between the second output and the first output of the OTA.
Aspect 11: The apparatus of any one of aspects 1-10, wherein the second PFET includes a gate configured to receive an input signal, and wherein the FVF is configured to generate an output signal at a drain of the first PFET and a source of the second PFET, wherein the output signal is based on the input signal.
Aspect 12: An apparatus, comprising: a flipped voltage follower (FVF) including a first current source, a first n-channel field effect transistor (NFET), and a second NFET coupled in series between an upper voltage rail and a lower voltage rail; and a bias voltage control circuit coupled to a node between the first current source and the first NFET.
Aspect 13: The apparatus of aspect 12, wherein the bias voltage control circuit comprises: an operational amplifier including a first input configured to receive a first voltage, a second input coupled to the node between the first current source and the first NFET, and an output; and a variable voltage source including a first terminal coupled to the node between the first current source and the first NFET, a second terminal coupled to a gate of the second NFET, and a control input coupled to the output of the operational amplifier.
Aspect 14: The apparatus of aspect 12, wherein the bias voltage control circuit comprises: an operational transconductance amplifier (OTA) including a first input configured to receive a first voltage, a second input coupled to the node between the first current source and the first NFET, a first output coupled to the node between the first current source and the first NFET, and a second output; and a variable voltage source comprising a resistor and a second current source, wherein the resistor is coupled between the node between the first current source and the first NFET and a gate of the second NFET, and wherein the second current source is coupled between the gate of the second NFET and the lower voltage rail.
Aspect 15: The apparatus of aspect 14, wherein the OTA, based on the first voltage, is configured to supply a first current flowing from the first output through the resistor and supply a second current flowing from the second output to the second current source to control a second voltage at the node between the first current source and the first NFET.
Aspect 16: The apparatus of aspect 12, wherein the bias voltage control circuit comprises: a bias voltage generator including an output; an operational transconductance amplifier (OTA) including a first input coupled to the output of the bias voltage generator, a second input coupled to the node between the first current source and the first NFET, a first output coupled to the node between the first current source and the first NFET, and a second output coupled to a gate of the second NFET; and a variable voltage source including at least a portion coupled between the first output and the second output of the OTA.
Aspect 17: The apparatus of aspect 16, wherein the bias voltage generator comprises: a first p-channel field effect transistor (PFET) including a source coupled to the upper voltage rail; a second PFET including a source coupled to a drain of the first PFET, and a gate and a drain coupled to a gate of the first PFET; and a second current source coupled between the drain of the second PFET and the lower voltage rail, wherein the drain of the first PFET and the source of the second PFET serve as the output of the bias voltage generator.
Aspect 18: The apparatus of aspect 16 or 17, wherein the OTA comprises: a first input differential NFET including a gate coupled to the output of the bias voltage generator; a second input differential NFET including a gate coupled to the node between the first current source and the first NFET; a first p-channel field effect transistor (PFET) including a source coupled to the upper voltage rail, and a gate and a drain coupled to a drain of the first input differential NFET; a second current source coupled between the respective sources of the first and second input differential NFETs and the lower voltage rail; a second PFET including a source coupled to the upper voltage rail, a gate coupled to the gate and the drain of the first PFET, and a drain coupled to the node between the first current source and the first NFET; a third PFET including a source coupled to the upper voltage rail, and a gate and a drain coupled to a drain of the second input differential NFET; and a fourth PFET including a source coupled to the upper voltage rail, a gate coupled to the gate and the drain of the third PFET, and a source coupled to the gate of the second NFET.
Aspect 19: The apparatus of any of aspects 16 to 18, wherein the variable voltage source comprises: a parallel-coupled resistor and capacitor coupled between the first output and the second output of the OTA; and a second current source coupled between the second output of the OTA and the lower voltage rail.
Aspect 20: A method of driving a load, comprising: providing an input signal to a gate of a first field effect transistor (FET) coupled between a current source and a second FET of a flipped voltage follower (FVF); generating an output signal for driving the load based on the input signal at an output of the FVF, wherein the output is coupled to a source of the first FET and a drain of the second FET; and controlling a voltage difference between a gate of the second FET and a node between the first FET and the current source.

The previous description of the disclosure is provided to enable any person skilled in the art to make or use the disclosure. Various modifications to the disclosure will be readily apparent to those skilled in the art, and the generic principles defined herein may be applied to other variations without departing from the spirit or scope of the disclosure. Thus, the disclosure is not intended to be limited to the examples described herein but is to be accorded the widest scope consistent with the principles and novel features disclosed herein.

What is claimed:

1. An apparatus, comprising:
a flipped voltage follower (FVF) including a first p-channel field effect transistor (PFET), a second PFET, and a first current source coupled in series between an upper voltage rail and a lower voltage rail; and
a bias voltage control circuit coupled to a node between the second PFET and the first current source.

2. The apparatus of claim 1, wherein the bias voltage control circuit is configured to:
receive a first voltage; and
control a second voltage at the node between the second PFET and the first current source based on the first voltage.

3. The apparatus of claim 2, wherein the bias voltage control circuit comprises:
an operational amplifier including a first input configured to receive the first voltage, a second input coupled to the node between the second PFET and the first current source, and an output; and
a variable voltage source including a first terminal coupled to a gate of the first PFET, a second terminal coupled to the node between the second PFET and the first current source, and a control input coupled to the output of the operational amplifier.

4. The apparatus of claim 3, wherein the operational amplifier is configured to control the variable voltage source to control the second voltage at the node between the second PFET and the first current source based on the first voltage.

5. The apparatus of claim 1, wherein the bias voltage control circuit comprises:
an operational transconductance amplifier (OTA) including a first input configured to receive a first voltage, a second input coupled to the node between the second PFET and the first current source, a first output coupled to the node between the second PFET and the first current source, and a second output coupled to a gate of the first PFET; and
a variable voltage source comprising a second current source and a resistor, wherein the second current source is coupled between the upper voltage rail and the gate of the first PFET, and wherein the resistor is coupled between the gate of the first PFET and the node between the second PFET and the first current source.

6. The apparatus of claim 5, wherein the OTA, based on the first voltage, is configured to draw a first current into the first output from the second current source via the resistor and draw a second current into the second output directly from the second current source to control a second voltage at the node between the second PFET and the first current source.

7. The apparatus of claim 1, wherein the bias voltage control circuit comprises:
a bias voltage generator including an output;
an operational transconductance amplifier (OTA) including a first input coupled to the output of the bias voltage generator, a second input coupled to the node between the second PFET and the first current source, a first output coupled to the node between the second PFET and the first current source, and a second output coupled to a gate of the first PFET; and
a variable voltage source including at least a portion coupled between the second output and the first output of the OTA.

8. The apparatus of claim 7, wherein the bias voltage generator comprises:
a second current source;
a first n-channel field effect transistor (NFET), wherein the second current source is coupled between the upper voltage rail and a drain and a gate of the first NFET; and
a second NFET including a drain coupled to a source of the first NFET, a gate coupled to the gate and drain of the first NFET, and a source coupled to the lower voltage rail, wherein the source of the first NFET and the drain of the second NFET serve as the output of the bias voltage generator.

9. The apparatus of claim 7, wherein the OTA comprises:
a first input differential PFET including a gate coupled to the output of the bias voltage generator;
a second input differential PFET including a gate coupled to the node between the second PFET and the first current source;
a second current source coupled between the upper voltage rail and respective sources of the first and second input differential PFETs;
a first n-channel field effect transistor (NFET) including a drain and a gate coupled to a drain of the first input differential PFET, and a source coupled to the lower voltage rail;
a second NFET including a drain coupled to the node between the second PFET and the first current source, a gate coupled to the gate and the drain of the first NFET, and a source coupled to the lower voltage rail;
a third NFET including a drain and a gate coupled to a drain of the second input differential PFET, and a source coupled to the lower voltage rail; and
a fourth NFET including a drain coupled to the gate of the first PFET, a gate coupled to the gate and the drain of the third NFET, and a source coupled to the lower voltage rail.

10. The apparatus of claim 7, wherein the variable voltage source comprises:
a second current source coupled between the upper voltage rail and the second output of the OTA; and
a parallel-coupled resistor and capacitor coupled between the second output and the first output of the OTA.

11. The apparatus of claim 1, wherein the second PFET includes a gate configured to receive an input signal, and wherein the FVF is configured to generate an output signal at a drain of the first PFET and a source of the second PFET, wherein the output signal is based on the input signal.

12. An apparatus, comprising:
a flipped voltage follower (FVF) including a first current source, a first n-channel field effect transistor (NFET), and a second NFET coupled in series between an upper voltage rail and a lower voltage rail; and
a bias voltage control circuit coupled to a node between the first current source and the first NFET.

13. The apparatus of claim 12, wherein the bias voltage control circuit comprises:
an operational amplifier including a first input configured to receive a first voltage, a second input coupled to the node between the first current source and the first NFET, and an output; and
a variable voltage source including a first terminal coupled to the node between the first current source and the first NFET, a second terminal coupled to a gate of the second NFET, and a control input coupled to the output of the operational amplifier.

14. The apparatus of claim 12, wherein the bias voltage control circuit comprises:
an operational transconductance amplifier (OTA) including a first input configured to receive a first voltage, a second input coupled to the node between the first current source and the first NFET, a first output coupled to the node between the first current source and the first NFET, and a second output; and
a variable voltage source comprising a resistor and a second current source, wherein the resistor is coupled between the node between the first current source and the first NFET and a gate of the second NFET, and wherein the second current source is coupled between the gate of the second NFET and the lower voltage rail.

15. The apparatus of claim 14, wherein the OTA, based on the first voltage, is configured to supply a first current flowing from the first output through the resistor and supply a second current flowing from the second output to the second current source to control a second voltage at the node between the first current source and the first NFET.

16. The apparatus of claim 12, wherein the bias voltage control circuit comprises:
a bias voltage generator including an output;
an operational transconductance amplifier (OTA) including a first input coupled to the output of the bias voltage generator, a second input coupled to the node between the first current source and the first NFET, a first output coupled to the node between the first current source and the first NFET, and a second output coupled to a gate of the second NFET; and
a variable voltage source including at least a portion coupled between the first output and the second output of the OTA.

17. The apparatus of claim 16, wherein the bias voltage generator comprises:
a first p-channel field effect transistor (PFET) including a source coupled to the upper voltage rail;
a second PFET including a source coupled to a drain of the first PFET, and a gate and a drain coupled to a gate of the first PFET; and
a second current source coupled between the drain of the second PFET and the lower voltage rail, wherein the drain of the first PFET and the source of the second PFET serve as the output of the bias voltage generator.

18. The apparatus of claim 16, wherein the OTA comprises:
a first input differential NFET including a gate coupled to the output of the bias voltage generator;
a second input differential NFET including a gate coupled to the node between the first current source and the first NFET;
a first p-channel field effect transistor (PFET) including a source coupled to the upper voltage rail, and a gate and a drain coupled to a drain of the first input differential NFET;
a second current source coupled between the respective sources of the first and second input differential NFETs and the lower voltage rail;
a second PFET including a source coupled to the upper voltage rail, a gate coupled to the gate and the drain of the first PFET, and a drain coupled to the node between the first current source and the first NFET;
a third PFET including a source coupled to the upper voltage rail, and a gate and a drain coupled to a drain of the second input differential NFET; and
a fourth PFET including a source coupled to the upper voltage rail, a gate coupled to the gate and the drain of the third PFET, and a source coupled to the gate of the second NFET.

19. The apparatus of claim 16, wherein the variable voltage source comprises:
a parallel-coupled resistor and capacitor coupled between the first output and the second output of the OTA; and
a second current source coupled between the second output of the OTA and the lower voltage rail.

20. A method, comprising:
providing an input signal to a gate of a first field effect transistor (FET) coupled between a current source and a second FET of a flipped voltage follower (FVF);
generating an output signal based on the input signal at an output of the FVF, wherein the output is coupled to a source of the first FET and a drain of the second FET; and
controlling a voltage difference between a gate of the second FET and a node between the first FET and the current source.
